(19) United States
(12) Patent Application Publication
(10) Pub. No.: US 2025/0390134 A1
(43) Pub. Date: Dec. 25, 2025

(54) STRESS COMPENSATION CIRCUIT

(71) Applicant: Texas Instruments Incorporated, Dallas, TX (US)

(72) Inventors: Sandeep Shylaja KRISHNAN, Bangalore (IN); Tallam VISHWANATH, Bangalore (IN)

(73) Assignee: Texas Instruments Incorporated, Dallas, TX (US)

(21) Appl. No.: 18/820,430

(22) Filed: Aug. 30, 2024

(30) Foreign Application Priority Data
Jun. 25, 2024 (IN) 202441048517

(51) Int. Cl. G05F 3/30; H03K 17/14

(52) U.S. Cl. CPC G05F 3/30; H03K 17/145

(57) ABSTRACT

A circuit includes a first transistor, a second transistor, and a third transistor. The first transistor has a first terminal, a second terminal, and a control terminal coupled to the first terminal. The second transistor has a first terminal, a second terminal coupled to the first terminal of the first transistor, and a control terminal coupled to the second terminal of the first transistor. The third transistor has a first terminal configured to provide a stress compensation current, a second terminal coupled to the control terminal of the second transistor, and a control terminal coupled to the first terminal of the second transistor.

### CROSS-REFERENCE TO RELATED APPLICATIONS

This application claims priority to Indian Provisional Application No. 202441048517, filed Jun. 25, 2024, entitled “Stress Compensation Circuit,” which is hereby incorporated by reference in its entirety.

### BACKGROUND

Many circuits and devices (e.g., linear or switching voltage regulators), need a precise reference voltage to operate. A band gap reference circuit may be used to generate such a reference voltage. Band gap voltage reference circuits generate a temperature-stable voltage by combining a p-n junction voltage with a thermal voltage. A band gap reference circuit generates a complementary-to-absolute-temperature (CTAT) voltage/current and a proportional-to-absolute-temperature (PTAT) voltage/current. The CTAT component decreases with increasing temperature (I.e., the CTAT component has a negative temperature coefficient), and the PTAT component increases with increasing temperature (i.e., the PTAT component has a positive temperature coefficient). The bandgap reference circuit combines the PTAT and CTAT voltages or currents such that their respective temperature coefficients cancel each other out to produce a temperature stable voltage or current.

### SUMMARY

In one example, a circuit includes a first transistor, a second transistor, and a third transistor. The first transistor has a first terminal, a second terminal, and a control terminal coupled to the first terminal. The second transistor has a first terminal, a second terminal coupled to the first terminal of the first transistor, and a control terminal coupled to the second terminal of the first transistor. The third transistor has a first terminal configured to provide a stress compensation current, a second terminal coupled to the control terminal of the second transistor, and a control terminal coupled to the first terminal of the second transistor.

In another example, a circuit includes a first transistor, a second transistor, a third transistor, and a fourth transistor. The first transistor has a first terminal, a second terminal, and a control terminal coupled to the first terminal. The second transistor has a first terminal coupled to the control terminal of the first transistor, a second terminal, and a control terminal coupled to the second terminal of the first transistor. The third transistor has a first terminal coupled to the second terminal of the second transistor, a second terminal, and a control terminal. The fourth transistor has a first terminal coupled to the control terminal of the third transistor, a second terminal, and a control terminal coupled to the second terminal of the third transistor and the second terminal of the fourth transistor.

In a further example, a reference voltage circuit includes a band gap circuit and a stress compensation circuit. The band gap circuit has an output configured to provide a reference voltage, and an input configured to receive a stress compensation signal. The stress compensation circuit has an output coupled to the input of the band gap circuit. The stress compensation circuit is configured to generate the stress compensation signal based on a difference of a base-to-emitter voltage of an NPN transistor and a base-to-emitter voltage of a PNP transistor.

### BRIEF DESCRIPTION OF THE DRAWINGS

FIG. 1 is schematic diagram of an example voltage reference circuit that includes stress compensation.

FIG. 2 is a schematic diagram of an example stress compensation circuit suitable for use in the voltage reference circuit of FIG. 1.

FIG. 3 is a schematic diagram of an example stress compensation circuit suitable for use in the voltage reference circuit of FIG. 1.

FIG. 4 is a schematic diagram of an example resistor trim circuit suitable for use in the stress compensation circuits of FIGS. 2 and 3.

FIG. 5 is a schematic diagram of an example resistor trim circuit suitable for use in the stress compensation circuits of FIGS. 2 and 3.

### DETAILED DESCRIPTION

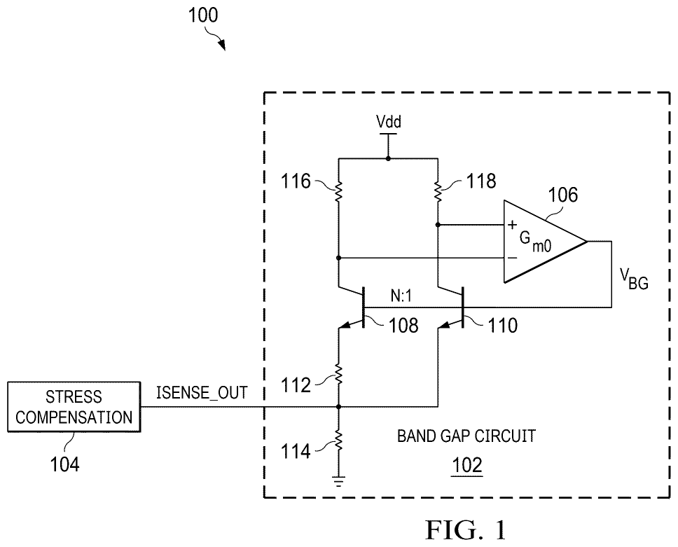

FIG. 1 is schematic diagram of an example voltage reference circuit 100. The voltage reference circuit 100 includes a band gap circuit 102 and a stress compensation circuit 104. The band gap circuit 102 is illustrated as a Brokaw band gap circuit, but other band gap circuit implementations may also be used. In a Brokaw bandgap circuit, negative feedback through the amplifier results in a constant current through two bipolar transistors with different emitter areas.

The band gap circuit 102 includes an amplifier 106, transistors 108 and 110, and resistors 112, 114, 116, and 118. The transistors 108 and 110 are illustrated as NPN bipolar transistors, but in some examples of the band gap circuit 102, the transistors 108 and 110 may be PNP bipolar transistors. The transistor 108 may be scaled N:1 relative to the transistor 110. The transistor 108 has a first terminal (e.g., collector) coupled to a first input (e.g., inverting input) of the amplifier 106, a second terminal (e.g., emitter) coupled to a first terminal the resistor 112, and a control terminal (e.g., base) coupled to the output of the amplifier 106. The transistor 110 has a first terminal (e.g., collector) coupled to a second input (e.g., non-inverting input) of the amplifier 106, a second terminal (e.g., emitter) coupled to a second terminal of the resistor 112, and a control terminal (e.g., base) coupled to the output of the amplifier 106. The resistor 114 has a first terminal coupled to the second terminal of the resistor 112, and a second terminal coupled to a reference terminal (e.g., ground). The resistor 116 is coupled between the first terminal of the transistor 108 and a power supply terminal (Vdd). The resistor 118 is coupled between the first terminal of the transistor 110 and the power supply terminal.

In the band gap circuit 102, the base-to-emitter voltage (V_{BE}) of the transistors 108 and 110 has a negative temperature coefficient (is complementary to absolute temperature (CTAT)), and the difference between the V_{BE} of the transistor 108 and the V_{BE} of the transistor 110 has a positive temperature coefficient) (is proportional to absolute temperature (PTAT)). The amplifier 106 sums the CTAT and PTAT voltages to produce an output voltage V_{BG} that is independent of temperature. The band gap circuit 102 may generate V_{BG} as:

$${V}_{BG} = {nV}_{BE} + {ΔV}_{BE} ( 1 + \frac{{R}_{2}}{{R}_{1}} ) \qquad ( 1 )$$

where:
nV_{BE} is the base-to-emitter voltage of the transistor 108;
ΔV_{BE} is the difference between the V_{BE} of the transistor 108 and the V_{BE} of the transistor 110;
R₂ is the resistance of the resistor 114; and
R₁ is the resistance of the resistor 112.

The band gap circuit 102 may be provided on an integrated circuit. The integrated circuit is subject to stress through the lead frame on which the integrated circuit is mounted, the encapsulation material surrounding the integrated circuit, or other components through which force is transferred to the integrated circuit. The stress affects the output voltage V_{BG} of the band gap circuit 102 causing inaccuracy therein. The output voltage of the band gap circuit 102 under stress V_{BG,S} may be defined as:

$${V}_{BG , S} = n ( {V}_{BE} + δ {V}_{BE} ) + ( {ΔV}_{BE} + {δΔV}_{BE} ) ( 1 + \frac{{R}_{2}}{{R}_{1}} ) \qquad ( 2 )$$

where:
δV_{BE} and δΔV_{BE} are stress induced change in V_{BE} and ΔV_{BE}.

Stress induced changes in the resistance of the resistors 112 and 114, and in ΔV_{BE} can be made very small by circuit layout. However, δV_{BE} cannot be reduced by circuit layout. The stress compensation circuit 104 generates a signal ISENSE_OUT that compensates for δV_{BE}. An output of the stress compensation circuit 104 is coupled to a compensation input of the band gap circuit 102 (e.g., the second terminal of the resistor 112). The stress compensation circuit 104 may generate ISENSE_OUT based on the difference between V_{BE} of an NPN bipolar transistor and V_{BE} of a PNP bipolar transistor. The stress compensation circuit 104 and the band gap circuit 102 may be provided on a same integrated circuit so that components of the stress compensation circuit 104 are subject to the same stress as the components of the band gap circuit 102.

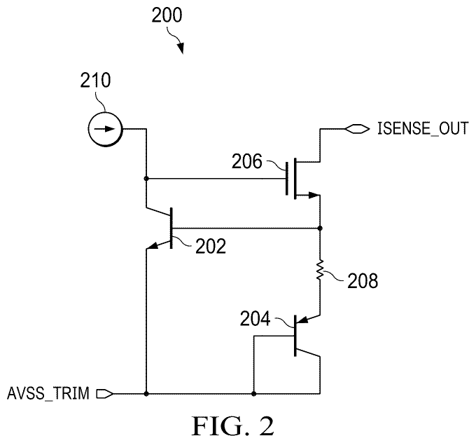

FIG. 2 is a schematic diagram of an example stress compensation circuit 200. The stress compensation circuit 200 is an example of the stress compensation circuit 104. The stress compensation circuit 200 includes transistors 202, 204, and 206, and a resistor 208. The transistor 202 may be an NPN bipolar transistor. The transistor 204 may be a PNP bipolar transistor. The transistor 206 may be an N-channel field effect transistor (NFET). The transistor 202 has a first terminal (e.g., collector) coupled to a current source 210. The current source 210 may provide a selected constant current (e.g., 125 nano-amperes). A second terminal (e.g., emitter) of the transistor 202 is coupled to a reference terminal (AVSS_TRIM) that provides a reference voltage to the stress compensation circuit 200. A control terminal (e.g., base) of the transistor 202 is coupled to a first terminal (e.g., emitter) of the transistor 204 via the resistor 208. The resistor 208 has a first terminal coupled to the control terminal of the transistor 202, and a second terminal coupled to the first terminal of the transistor 204. The resistance of the resistor 208 may be variable in some examples of the stress compensation circuit 200 to allow for trimming of ISENSE_OUT. A second terminal (e.g., collector) of the transistor 204 is coupled to a control terminal (e.g., base) of the transistor 204 and to the second terminal of the transistor 202. The transistor 206 is a cascode transistor. A first terminal (e.g., drain) of the transistor 206 is coupled to an output of the stress compensation circuit 200. For example, the first terminal of the transistor 206 may be coupled to the second terminal of the resistor 112 to provide ISENSE_OUT to the band gap circuit 102. A second terminal (e.g., source) of the transistor 206 is coupled to the control terminal of the transistor 202.

In the stress compensation circuit 200, the difference between the V_{BE} of the transistor 204 and the V_{BE} of the transistor 202 is provided across the resistor 208. The current flowing through the transistor 206 and the resistor 208 to produce the difference voltage across the resistor 208 is ISENSE_OUT. ISENSE_OUT flows from the band gap circuit 102 to compensate for δV_{BE}. As stress affects the integrated circuit on which the band gap circuit 102 and the stress compensation circuit 200 are provided, the V_{BE} of the transistors 108, 110, 202 and transistor 204 changes. Accordingly, ISENSE_OUT represents the change in V_{BE} of the transistors 202 and 204 due to stress, and ISENSE_OUT is received by the band gap circuit 102 in order to compensate the band gap circuit 102 for stress.

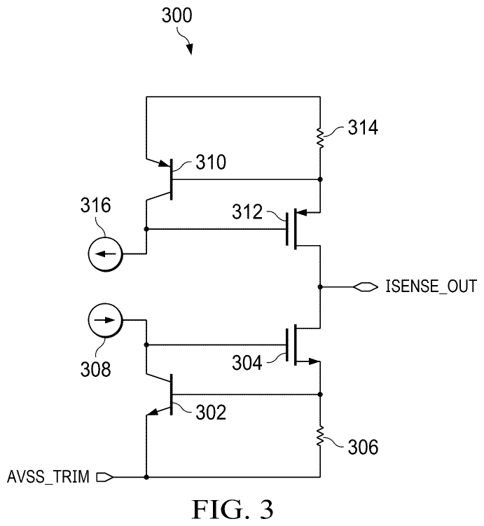

FIG. 3 is a schematic diagram of an example stress compensation circuit 300. The stress compensation circuit 300 is an example of the stress compensation circuit 104. The stress compensation circuit 300 includes transistors 302, 304, 310, and 312, and resistors 306 and 314. The transistor 302 may be an NPN bipolar transistor. The transistor 310 may be a PNP bipolar transistor. The transistor 304 may be an NFET. The transistor 312 may be a p-channel field effect transistor (PFET). The resistor 306 and the resistor 314 may have variable resistance in some examples of the stress compensation circuit 300 to allow for trimming of ISENSE_OUT.

The transistor 302 has a first terminal (e.g., collector) coupled to a current source 308. The current source 308 may provide a selected constant current (e.g., 125 nano-amperes) to the stress compensation circuit 300. A second terminal (e.g., emitter) of the transistor 302 is coupled to a reference terminal (AVSS_TRIM) that provides a reference voltage to the stress compensation circuit 300. A control terminal (e.g., base) of the transistor 302 is coupled to the second terminal of the transistor 302 via the resistor 306. The resistor 306 has a first terminal coupled to the control terminal of the transistor 302, and a second terminal coupled to the second terminal of the transistor 302.

The transistor 304 operates as a cascode transistor that isolates the transistor 302 from other circuitry. The transistor 304 has a first terminal (e.g., drain) coupled to an output terminal of the stress compensation circuit 300 for providing ISENSE_OUT to the band gap circuit 102, a second terminal (e.g., source) coupled to the control terminal of the transistor 302, and a control terminal (e.g., gate) coupled to the first terminal of the transistor 302. Current flows through the transistor 304 and the resistor 306 to develop a voltage corresponding to the V_{BE} of the transistor 302 across the resistor 306.

The transistor 310 has a first terminal (e.g., collector) coupled to a current source 316. The current source 316 may provide a selected constant current (e.g., 125 nano-amperes) to the stress compensation circuit 300. A second terminal (e.g., emitter) of the transistor 310 is coupled to a control terminal (e.g., base) of the transistor 310 via the resistor 314. The resistor 314 has a first terminal coupled to the control terminal of the transistor 310, and a second terminal coupled to the second terminal of the transistor 310.

The transistor 312 operates as a cascode transistor that isolates the transistor 310 from other circuitry. The transistor 312 has a first terminal (e.g., drain) coupled to the first terminal of the transistor 304 for providing ISENSE_OUT to the band gap circuit 102, a second terminal (e.g., source) coupled to the control terminal of the transistor 310, and a control terminal (e.g., gate) coupled to the first terminal of the transistor 310. Current flows through the transistor 312 and the resistor 314 to develop a voltage corresponding to the V_{BE} of the transistor 310 across the resistor 314. ISENSE_OUT is a sum of the currents flowing through the transistor 304 and the transistor 312, and represents the change in V_{BE} of the transistors 302 and transistor 310 due to stress. ISENSE_OUT is received by the band gap circuit 102 in order to compensate the band gap circuit 102 for stress.

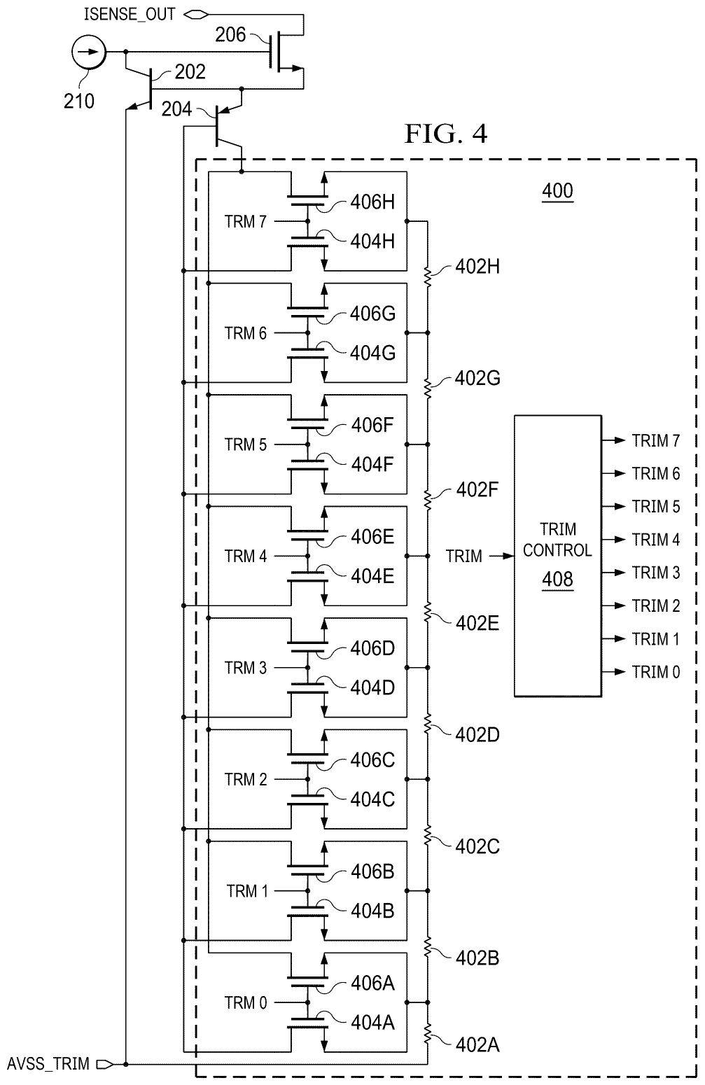

FIG. 4 is a schematic diagram of an example resistor circuit 400 suitable for use in the stress compensation circuits 200 and 300. In the example of FIG. 4, the transistors 202, 204, and 206 are shown for context. The resistance of the resistor circuit 400 can be selected to trim ISENSE_OUT at manufacture of an integrated circuit that includes the band gap circuit 102 and the stress compensation circuit 200 or the stress compensation circuit 300. The resistor circuit 400 includes resistors 402A through 402H, the transistors 404A through 404H, transistors 406A through 406H, and a trim control circuit 408. The resistors 402A through 402H are coupled in series. A first terminal of the resistor 402A is coupled to the second terminal of the transistor 202, and a second terminal of the resistor 402A is coupled to the first terminal of the resistor 402B. A second terminal of the resistor 402B is coupled to a first terminal of the resistor 402C, etc.

The transistors 404A through 404H, and transistors 406A through 406H operate as switches that couple the second terminal of the transistor 204 to the control terminal of the transistor 204, and couple the second terminal of the transistor 204 and the control terminal of the transistor 204 to the first terminal of the transistor 202 via selected resistors of the resistors 402A through 402H. Each of the transistors 404A through 404H is coupled between a second terminal of one of the resistors 402A through 402H and the control terminal of the transistor 204. Each of the transistors 406A through 406H is coupled between the second terminal of one of the resistors 402A through 402H and the second terminal of the transistor 204. The transistor 404A is coupled between the second terminal of the resistor 402A and the control terminal of the transistor 204, and the transistor 406A is coupled between the second terminal of the resistor 402A and the second terminal of the transistor 204. The transistor 404B is coupled between the second terminal of the resistor 402B and the control terminal of the transistor 204, and the transistor 406B is coupled between the second terminal of the resistor 402B and the second terminal of the transistor 204. The transistor 404C is coupled between the second terminal of the resistor 402C and the control terminal of the transistor 204, and the transistor 406C is coupled between the second terminal of the resistor 402C and the second terminal of the transistor 204.

The transistor 404D is coupled between the second terminal of the resistor 402D and the control terminal of the transistor 204, and the transistor 406D is coupled between the second terminal of the resistor 402D and the second terminal of the transistor 204. The transistor 404E is coupled between the second terminal of the resistor 402E and the control terminal of the transistor 204, and the transistor 406E is coupled between the second terminal of the resistor 402E and the second terminal of the transistor 204. The transistor 404F is coupled between the second terminal of the resistor 402F and the control terminal of the transistor 204, and the transistor 406F is coupled between the second terminal of the resistor 402F and the second terminal of the transistor 204. The transistor 404G is coupled between the second terminal of the resistor 402G and the control terminal of the transistor 204, and the transistor 406G is coupled between the second terminal of the resistor 402G and the second terminal of the transistor 204. The transistor 404H is coupled between the second terminal of the resistor 402H and the control terminal of the transistor 204, and the transistor 406H is coupled between the second terminal of the resistor 402H and the second terminal of the transistor 204.

The trim control circuit 408 turns the transistors 404A through 404H, and transistors 406A through 406H on or off to select the resistance of the resistor circuit 400. The trim control circuit 408 has an input for receiving a trim signal (TRIM) that specifies which of the transistors is to be turned on. The trim signal may specify a binary code. For example, in the implementation of the resistor circuit 400 shown in FIG. 4, TRIM may specify a three bit binary code. The trim control circuit 408 may be a N to 2N binary decoder with level shifting to drive the transistors. The trim control circuit 408 has outputs coupled to the control terminals of the transistors 404A through 404H, and the control terminals of the transistors 406A through 406H. A first output of the trim control circuit 408 is coupled to the control terminals of the transistors 404A and 406A to select resistor 402A using a signal TRM 0. A second output of the trim control circuit 408 is coupled to the control terminals of the transistors 404B and 406B to select resistors 402A and 402B using a signal TRM 1. A third output of the trim control circuit 408 is coupled to the control terminals of the transistors 404C and 406C to select resistors 402A through 402C using a signal TRM 2.

A fourth output of the trim control circuit 408 is coupled to the control terminals of the transistors 404D and 406D to select resistors 402A through 402D using a signal TRM 3. A fifth output of the trim control circuit 408 is coupled to the control terminals of the transistors 404E and 406E to select resistors 402A through 402E using a signal TRM 4. A sixth output of the trim control circuit 408 is coupled to the control terminals of the transistors 404F and 406F to select resistors 402A through 402F using a signal TRM 5. A seventh output of the trim control circuit 408 is coupled to the control terminals of the transistors 404G and 406G to select resistors 402A through 402G using a signal TRM 6. An eighth output of the trim control circuit 408 is coupled to the control terminals of the transistors 404H and 406H to select resistors 402A through 402H using a signal TRM 7.

Various examples of the resistor circuit 400 may include more or less resistors and switches than are shown in FIG. 4, with a corresponding change in the number of outputs of the trim control circuit 408.

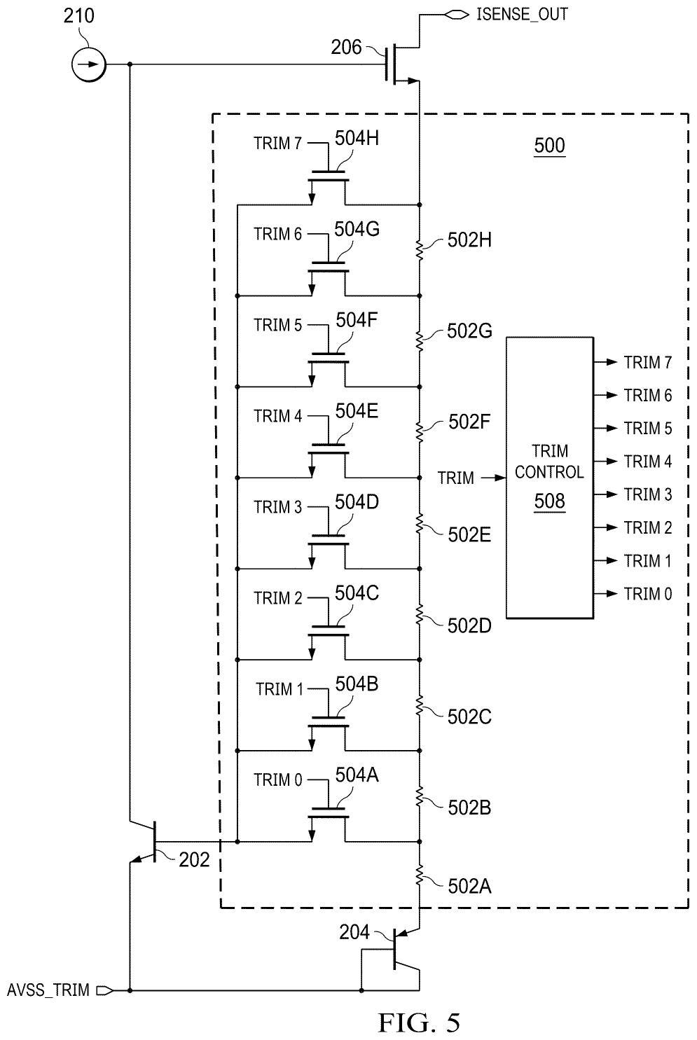

FIG. 5 is a schematic diagram of an example resistor circuit 500 suitable for use in the stress compensation circuits 200 and 300. In the example of FIG. 5, the transistors 202, 204, and 206 are shown for context. The resistance of the resistor circuit 500 can be selected to trim ISENSE_OUT at manufacture of an integrated circuit that includes the band gap circuit 102 and the stress compensation circuit 200 or the stress compensation circuit 300. The resistor circuit 500 includes resistors 502A through 502H, the transistors 504A through 504H, and a trim control circuit 508. The resistors 502A through 502H are coupled in series between the second terminal of the transistor 206 and the first terminal of the transistor 204. A first terminal of the resistor 502A is coupled to the first terminal of the transistor 204, and a second terminal of the resistor 502A is coupled to the first terminal of the resistor 502B. A second terminal of the resistor 502B is coupled to a first terminal of the resistor 502C, etc. A second terminal of the resistor 502H is coupled to the second terminal of the transistor 206.

The transistors 504A through 504H operate as switches that couple the second terminal of the transistor 206 to the control terminal of the transistor 202 via selected resistors of the resistors 502A through 502H. Each of the transistors 504A through 504H is coupled between a second terminal of one of the resistors 502A through 502H and the control terminal of the transistor 202. The transistor 504A is coupled between the second terminal of the resistor 502A and the control terminal of the transistor 202. The transistor 504B is coupled between the second terminal of the resistor 502B and the control terminal of the transistor 202. The transistor 504C is coupled between the second terminal of the resistor 502C and the control terminal of the transistor 202. The transistor 504D is coupled between the second terminal of the resistor 502D and the control terminal of the transistor 202. The transistor 504E is coupled between the second terminal of the resistor 502E and the control terminal of the transistor 202. The transistor 504F is coupled between the second terminal of the resistor 502F and the control terminal of the transistor 202. The transistor 504G is coupled between the second terminal of the resistor 502G and the control terminal of the transistor 202. The transistor 504H is coupled between the second terminal of the resistor 502H and the control terminal of the transistor 202.

The trim control circuit 508 turns the transistors 504A through 504H on or off to select the resistance of the resistor circuit 500. The trim control circuit 508 has an input for receiving a trim signal (TRIM) that specifies which of the transistors is to be turned on. The trim signal may specify a binary code. For example, in the implementation of the resistor circuit 500 shown in FIG. 5, TRIM may specify a three bit binary code. The trim control circuit 508 may be a N to 2N binary decoder with level shifting to drive the transistors. The trim control circuit 508 has outputs coupled to the control terminals of the transistors 504A through 504H. A first output of the trim control circuit 508 is coupled to the control terminal of the transistor 504A to select resistors 502B through 502H using a signal TRM 0. A second output of the trim control circuit 508 is coupled to the control terminal of the transistor 504B to select resistors 502C through 502H using a signal TRM 1. A third output of the trim control circuit 508 is coupled to the control terminal of the transistor 504C to select resistors 502D through 502H using a signal TRM 2. A fourth output of the trim control circuit 508 is coupled to the control terminal of the transistor 504D to select resistors 502E through 502H using a signal TRM 3. A fifth output of the trim control circuit 508 is coupled to the control terminal of the transistor 504E to select resistors 502F through 502H using a signal TRM 4. A sixth output of the trim control circuit 508 is coupled to the control terminal of the transistor 504F to select resistors 502G through 502H using a signal TRM 5. A seventh output of the trim control circuit 508 is coupled to the control terminal of the transistor 504G to select resistor 502H using a signal TRM 6. An eighth output of the trim control circuit 508 is coupled to the control terminal of the transistor 504H to couple the second terminal of the transistor 206 to the control terminal of the transistor 202 using signal TRM 7.

Various examples of the resistor circuit 500 may include more or less resistors and switches than are shown in FIG. 5, with a corresponding change in the number of outputs of the trim control circuit 508.

Examples of the stress compensation circuit 104 described herein improve the various product specifications that are impacted by an effect of mechanical stress exerted on a die by packaging. For a voltage reference, such as the voltage reference circuit 100, these specifications include long term drift, temperature drift, solder shift and thermal hysteresis. Long term drift is the change in output voltage over time. Solder shift is the shift in output voltage due to reflow soldering. Thermal hysteresis is the shift in the output voltage after the device is cycled through its operating temperature range.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “ON” or “enabled” means that the conduction channel of the FET is present and drain current may flow through the FET. References herein to a FET being “OFF” or “disabled” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. A circuit comprising:
a first transistor having a first terminal (collector), a second terminal (emitter), and a control terminal (base) coupled to the first terminal;
a second transistor having a first terminal (collector), a second terminal (emitter) coupled to the first terminal of the first transistor, and a control terminal (base) coupled to the second terminal of the first transistor; and
a third transistor having a first terminal (drain) configured to provide a stress compensation current, a second terminal (source) coupled to the control terminal of the second transistor, and a control terminal (gate) coupled to the first terminal of the second transistor.

2. The circuit of claim 1, further comprising a resistor having a first terminal coupled to the second terminal of the first transistor, and a second terminal coupled to the control terminal of the second transistor and the second terminal of the third transistor.

3. The circuit of claim 2, wherein:
the resistor is a first resistor;
the circuit includes:
a fourth transistor having a first terminal coupled to the second terminal of the first resistor, a second terminal coupled to the control terminal of the second transistor, and a control terminal;
a second resistor having a first terminal coupled to the second terminal of the first resistor, and a second terminal;
a fifth transistor having a first terminal coupled to the second terminal of the second resistor, a second terminal coupled to the control terminal of the second transistor, and a control terminal; and
a control circuit having a first output coupled to the control terminal of the first transistor, and a second output coupled to the control terminal of the second transistor.

4. The circuit of claim 1, wherein the first transistor is a PNP bipolar transistor, and the second transistor is an NPN bipolar transistor.

5. The circuit of claim 4, wherein the second terminal of the first transistor is an emitter, and the second terminal of the second transistor is an emitter.

6. The circuit of claim 1, further comprising a resistor circuit including:
a first resistor having a first terminal coupled to the second terminal of the second transistor, and a second terminal;
a first switch having a first terminal coupled to the second terminal of the first resistor, a second terminal coupled to the control terminal of the first transistor, a third terminal coupled to the control terminal of the first transistor, and a control input;
a second resistor having a first terminal coupled to the second terminal of the first resistor, and a second terminal; and
a second switch having a first terminal coupled to the second terminal of the second resistor, a second terminal coupled to the control terminal of the first transistor, a third terminal coupled to the control terminal of the first transistor, and a control input coupled to the control input of the first switch.

7. The circuit of claim 6, wherein the first switch includes:
a fourth transistor having a first terminal coupled to the second terminal of the first resistor, a second terminal coupled to the control terminal of the first transistor, and a control terminal; and
a fifth transistor having a first terminal coupled to the second terminal of the first resistor, a second terminal coupled to the first terminal of the first transistor, and a control terminal coupled to the control terminal of the fourth transistor.

8. The circuit of claim 1, further comprising a current source having an input coupled to the second terminal of the second transistor.

9. The circuit of claim 1, further comprising a bandgap reference circuit having a compensation input coupled to the second terminal of the third transistor.

10. A circuit comprising:
a first transistor having a first terminal, a second terminal, and a control terminal coupled to the first terminal;
a second transistor having a first terminal coupled to the control terminal of the first transistor, a second terminal, and a control terminal coupled to the second terminal of the first transistor;
a third transistor having a first terminal coupled to the second terminal of the second transistor, a second terminal, and a control terminal; and
a fourth transistor having a first terminal coupled to the control terminal of the third transistor, a second terminal, and a control terminal coupled to the second terminal of the third transistor and the second terminal of the fourth transistor.

11. The circuit of claim 10, further comprising a resistor having a first terminal coupled to the control terminal of the first transistor and a second terminal coupled to the control terminal of the first transistor and the first terminal of the second transistor.

12. The circuit of claim 11, wherein a resistance of the resistor is variable.

13. The circuit of claim 10, further comprising a resistor having a first terminal coupled to the second terminal of the fourth transistor and a second terminal coupled to the control terminal of the fourth transistor and the second terminal of the third transistor.

14. The circuit of claim 13, wherein a resistance of the resistor is variable.

15. The circuit of claim 10, further comprising:
a first current source having an input coupled to the second terminal of the first transistor; and
a second current source having an output coupled to the second terminal of the fourth transistor.

16. The circuit of claim 10, further comprising a bandgap reference circuit having a compensation input coupled to the second terminal of the second transistor.

17. A reference voltage circuit comprising:
a band gap circuit having an output configured to provide a reference voltage, and an input configured to receive a stress compensation signal; and
a stress compensation circuit having an output coupled to the input of the band gap circuit, the stress compensation circuit configured to generate the stress compensation signal based on a difference of a base-to-emitter voltage of an NPN transistor and a base-to-emitter voltage of a PNP transistor.

18. The reference voltage circuit of claim 17, wherein the stress compensation circuit includes:
a PNP transistor having a first terminal, a second terminal, and a control terminal coupled to the first terminal;
a NPN transistor having a first terminal, a second terminal coupled to the first terminal of the PNP transistor, and a control terminal coupled to the second terminal of the PNP transistor; and
a cascode transistor having a first terminal coupled to the input of the band gap circuit, a second terminal coupled to the control terminal of the NPN transistor, and a control terminal coupled to the first terminal of the NPN transistor.

19. The reference voltage circuit of claim 17, wherein the stress compensation circuit includes:
an NPN transistor having a first terminal, a second terminal, and a control terminal coupled to the first terminal;
a first cascode transistor having a first terminal coupled to the control terminal of the NPN transistor, a second terminal coupled to the input of the band gap circuit, and a control terminal coupled to the second terminal of the NPN transistor;
a second cascode transistor having a first terminal coupled to the second terminal of the first cascode transistor, a second terminal, and a control terminal; and
a PNP transistor having a first terminal coupled to the control terminal of the second cascode transistor, a second terminal, and a control terminal coupled to the second terminal of the second cascode transistor and the second terminal of the PNP transistor.

20. The reference voltage circuit of claim 17, further comprising a current source configured to provide a current at a collector of the NPN transistor or the PNP transistor.
